(19) United States
(12) Patent Application Publication
(10) Pub. No.: US 2016/0218701 A1
(43) Pub. Date: Jul. 28, 2016

(54) PHASE CONTROL CIRCUITS AND DATA OUTPUT DEVICES INCLUDING THE SAME

(71) Applicant: SK hynix Inc., Icheon-si (KR)

(72) Inventor: Min Sik HAN, Icheon-si Gyeonggi-do (KR)

(21) Appl. No.: 14/698,502

(22) Filed: Apr. 28, 2015

(30) Foreign Application Priority Data
Jan. 26, 2015 (KR) 10-2015-0011875

(51) Int. Cl. H03K 5/13

(52) U.S. Cl. CPC H03K 5/13; H03K 2005/00013

(57) ABSTRACT

Phase control circuits are provided. The phase control circuit may include a phase controller. The phase controller may compensate for a phase difference between a first phase signal of a rising clock signal and a second phase signal of a falling clock signal to generate a first internal clock signal. The phase controller may compensate for a phase difference between a first phase signal of the falling clock signal and a second phase signal of the rising clock signal to generate a second internal clock signal. Related data output devices are also provided.

### CROSS-REFERENCE TO RELATED APPLICATION

The present application claims priority under 35 U.S.C 119(a) to Korean Application No. 10-2015-0011875, filed on Jan. 26, 2015, in the Korean Intellectual Property Office, which is incorporated herein by reference in its entirety as set forth in full.

### BACKGROUND

1. Technical Field

Embodiments of the present disclosure generally relate to phase control circuits and data output devices including the same.

2. Related Art

Relatively fast semiconductor devices are increasingly in demand along with improved integration density. Synchronous devices operating in synchronization with external clock signals have been revealed to improve the operation speeds of the semiconductor devices.

At first, single data rate (SDR) synchronous semiconductor devices were proposed to improve the operation speeds of the SDR synchronous semiconductor devices. The SDR synchronous semiconductor devices may receive or output a single data piece through a single data pin for one cycle time of the external clock signal in synchronization with every rising edge of the external clock signal. However, high performance devices operating at a higher speed than the SDR synchronous semiconductor devices have been demanded to meet the requirements of high performance semiconductor systems. Accordingly, double data rate (DDR) synchronous semiconductor devices have been proposed recently.

The DDR synchronous semiconductor devices may receive or output the data in synchronization with every rising edge and every falling edge of the external clock signal. Thus, the DDR synchronous semiconductor devices may operate at speeds at least twice as faster than that of the SDR synchronous semiconductor devices even without increasing a frequency of the external clock signal.

Various circuits may be used in the DDR synchronous semiconductor devices to compensate for a phase difference between clock signals for inputting or outputting data. The phase difference between the clock signals may be due to a timing skew between DDR synchronous semiconductor devices and/or variation of process/voltage/temperature (PVT) conditions.

### SUMMARY

According to an embodiment, a phase control circuit may include a phase controller. The phase controller may be configured to compensate for a phase difference between a first phase signal of a rising clock signal and a second phase signal of a falling clock signal to generate a first internal clock signal. The phase controller may be configured to compensate for a phase difference between a first phase signal of the falling clock signal and a second phase signal of the rising clock signal to generate a second internal clock signal.

According to an embodiment, a data output device may include a phase controller and a data input/output (I/O) unit. The phase controller may be configured to receive a rising clock signal and a falling clock signal having different phases. The phase controller may be configured to synthesize a first phase signal of the rising clock signal and a second phase signal of the falling clock signal to generate a first internal clock signal. The phase controller may be configured to synthesize a first phase signal of the falling clock signal and a second phase signal of the rising clock signal to generate a second internal clock signal. The data I/O unit may be configured to output internal data as output data in synchronization with the first and second internal clock signals.

### BRIEF DESCRIPTION OF THE DRAWINGS

FIG. 1 is a block diagram illustrating a representation of an example of a data output device according to an embodiment.

FIG. 2 is a logic circuit diagram illustrating a representation of an example of a phase controller included in the data output device of FIG. 1.

FIG. 3 is a timing diagram illustrating a representation of an example of an operation of the data output device according to an embodiment.

FIG. 4 illustrates a block diagram of an example of a representation of a system employing a phase control circuit and/or data output device in accordance with the various embodiments discussed above with relation to FIGS. 1-3.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

Various embodiments may be directed to phase control circuits compensating for a phase difference between differential signals having different phases to generate internal clock signals having the same timing, and data output devices including the same.

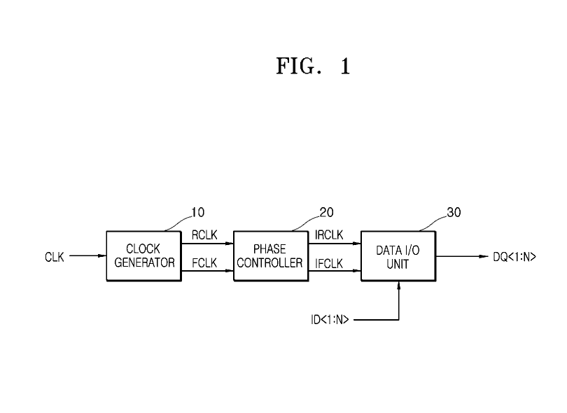

Referring to FIG. 1, a data output device according to an embodiment may include a clock generator 10, a phase controller 20 and a data input/output (I/O) unit 30.

The clock generator 10 may receive an external clock signal CLK to generate a rising clock signal RCLK. The rising clock signal RCLK may be created in synchronization with a rising edge of the external clock signal CLK. The clock generator 10 may receive an external clock signal CLK to generate a falling clock signal FCLK. The falling clock signal FCLK may be created in synchronization with a falling edge of the external clock signal CLK. For example, the rising clock signal RCLK and the falling clock signal FCLK may be generated to have two different phases opposite to each other.

The phase controller 20 may compensate for a phase difference between a first phase signal of the rising clock signal RCLK and a second phase signal of the falling clock signal FCLK to generate a first internal clock signal IRCLK. The phase controller 20 may compensate for a phase difference between a first phase signal of the falling clock signal FCLK and a second phase signal of the rising clock signal RCLK to generate a second internal clock signal IFCLK. The first phase signal of the rising clock signal RCLK may correspond to a signal that the rising clock signal RCLK is delayed without phase inversion. The second phase signal of the rising clock signal RCLK may correspond to a signal that the rising clock signal RCLK is delayed with phase inversion. The first phase signal of the falling clock signal FCLK may correspond to a signal that the falling clock signal FCLK is delayed without phase inversion. The second phase signal of the falling clock signal FCLK may correspond to a signal that the falling clock signal FCLK is delayed with phase inversion. The rising clock signal RCLK and the falling clock signal FCLK may be signals for synchronization of the data output device. In some embodiments, the rising clock signal RCLK and the falling clock signal FCLK may be set to be differential signals having phases that are opposite to each other.

The data I/O unit 30 may be synchronized with the first and second internal clock signals IRCLK and IFCLK to output internal data ID<1:N> as output data DQ<1:N> during a read operation. The data I/O unit 30 may be synchronized with the first and second internal clock signals IRCLK and IFCLK to receive the output data DQ<1:N> as the internal data ID<1:N> during a write operation.

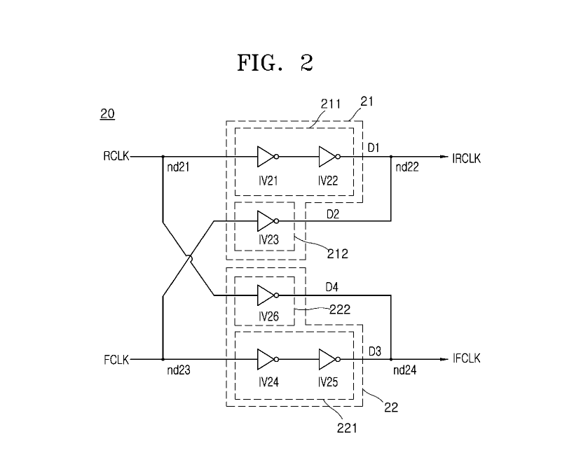

Referring to FIG. 2, the phase controller 20 corresponding to a phase control circuit may include a first synthesizer 21 and a second synthesizer 22.

The first synthesizer 21 may include a first delay unit 211 and a second delay unit 212.

The first delay unit 211 may be configured to include inverters IV21 and IV22 coupled in series between a node ND21 and a node ND22. The node ND21 may be configured to receive the rising clock signal RCLK. The node ND22 may be configured to receive the first internal clock signal IRCLK and is where the first internal clock signal IRCLK is outputted. The first delay unit 211 may retard the rising clock signal RCLK by a first delay time and may output the delayed rising clock signal RCLK as a first delay signal D1 through the node ND22. The first delay time may correspond to a total delay time of the inverters IV21 and IV22. FIG. 2 illustrates an example in which the first delay unit 211 is configured to have two inverters, but the present disclosure is not limited to only have two inverters. For example, the number of the inverters constituting the first delay unit 211 may be different according to the various embodiments.

The second delay unit 212 may be configured to include a single inverter IV23 coupled between a node ND23 and the node ND22. The falling clock signal FCLK may be applied to the node ND23. The second delay unit 212 may reverse and retard the falling clock signal FCLK by a second delay time and may output the inversed and delayed falling clock signal FCLK as a second delay signal D2 through the node ND22. The second delay time may correspond to a delay time of the inverter IV23. For example, FIG. 2 illustrates the second delay unit 212 configured to have a single inverter, but the embodiments are not limited to a single inverter. For example, the number of the inverters constituting the second delay unit 212 may be different according to the various embodiments. For example, the number of the inverters constituting the second delay unit 212 may be less or greater than the number of the inverters constituting the first delay unit 211 by one. For example, one of the first and second delay units 211 and 212 may inversely buffer an input signal thereof to generate an output signal thereof, and the other of the first and second delay units 211 and 212 may merely buffer an input signal thereof to generate an output signal thereof.

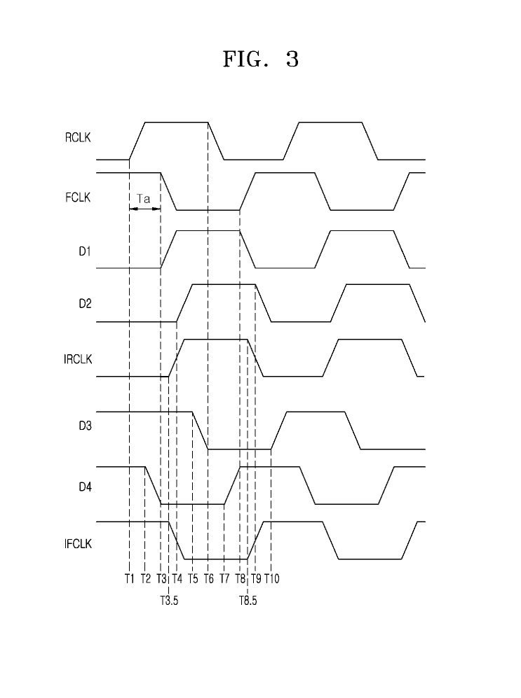

The first synthesizer 21 may generate the first internal clock signal IRCLK by synthesizing the first delay signal D1 and the second delay signal. The first delay signal D1 may have the same phase as the first phase signal of the rising clock signal RCLK. The second delay signal D2 may have the same phase as the second phase signal of the falling clock signal FCLK. An operation for generating the first internal clock signal IRCLK by synthesizing the first and second delay signals D1 and D2 will be described below with reference to FIG. 3 later.

The second synthesizer 22 may include a third delay unit 221 and a fourth delay unit 222.

The third delay unit 221 may be configured to include inverters IV24 and IV25 coupled in series between the node ND23 and the node ND24. The node ND23 may be configured to receive the falling clock signal FCLK the node ND24 may be configured to receive the second internal clock signal IFCLK and is where the second internal clock signal IFCLK is outputted. The third delay unit 221 may retard the falling clock signal FCLK by the first delay time and may output the delayed falling clock signal FCLK as a third delay signal D3 through the node ND24. The first delay time may correspond to a total delay time of the inverters IV24 and IV25. FIG. 2 illustrates an example in which the third delay unit 221 is configured to have two inverters, but the present disclosure is not limited to only have two inverters. For example, the number of the inverters constituting the third delay unit 221 may be different according to the various embodiments. In an embodiment, the third delay unit 221 may be realized to have the same delay time or substantially the same delay time as the first delay unit 211.

The fourth delay unit 222 may be configured to include a single inverter IV26 coupled between the node ND21 and the node ND24. The fourth delay unit 222 may reverse and retard the rising clock signal RCLK by the second delay time and may output the inversed and delayed rising clock signal RCLK as a fourth delay signal D4 through the node ND24. The second delay time may correspond to a delay time of the inverter IV26. For example, FIG. 2 illustrates the fourth delay unit 222 configured to have a single inverter, but the embodiments are not limited to a single inverter. For example, the number of the inverters constituting the fourth delay unit 222 may be different according to the various embodiments. For example, the number of the inverters constituting the fourth delay unit 222 may be less or greater than the number of the inverters constituting the third delay unit 221 by one. In an embodiment, the fourth delay unit 222 may be realized to have the same delay time or substantially the same delay time as the second delay unit 212.

The second synthesizer 22 may generate the second internal clock signal IFCLK by synthesizing the third delay signal D3 and the fourth delay signal. The third delay signal D3 may have the same phase as the first phase signal of the falling clock signal FCLK. The fourth delay signal D4 may have the same phase as the second phase signal of the rising clock signal RCLK. An operation for generating the second internal clock signal IFCLK by synthesizing the third and fourth delay signals D3 and D4 will be described hereinafter with reference to FIG. 3.

An operation of the data output device having the aforementioned configuration will be described hereinafter with reference to FIGS. 1, 2 and 3 in conjunction with an example in which a phase difference between the rising clock signal RCLK and the falling clock signal FCLK is compensated to generate the first and second internal clock signals IRCLK and IFCLK when the phase difference between the rising clock signal RCLK and the falling clock signal FCLK exists.

Referring to FIGS. 1, 2 and 3, the cock generator 10 may receive the external clock signal CLK to generate the rising clock signal RCLK created in synchronization with a rising edge of the external clock signal CLK and the falling clock signal FCLK created in synchronization with a falling edge of the external clock signal CLK. For example, in an embodiment, the rising clock signal RCLK and the falling clock signal FCLK may be generated to have two different phases opposite to each other. However, in an embodiment, there may be a phase difference Ta between the rising clock signal RCLK and the falling clock signal FCLK, as illustrated in FIG. 3. In an embodiment, the phase difference Ta may correspond to a period from a point of time “T1” to a point of time “T3”.

First, the fourth delay unit 222 of the second synthesizer 22 may inversely retard the rising clock signal RCLK generated at the point of time “T1” by the second delay time to generate the fourth delay signal D4 toggled from a logic “high” level to a logic “low” level at a point of time “T2”.

Next, the first delay unit 211 of the first synthesizer 21 may retard the rising clock signal RCLK generated at the point of time “T1” by the first delay time to generate the first delay signal D1 toggled from a logic “low” level to a logic “high” level at the point of time “T3”.

Next, the second delay unit 212 of the first synthesizer 21 may inversely retard the falling clock signal FCLK generated at the point of time “T3” by the second delay time to generate the second delay signal D2 toggled from a logic “low” level to a logic “high” level at a point of time “T4”.

The first synthesizer 21 may synthesize the first delay signal D1 toggled from a logic “low” level to a logic “high” level at the point of time “T3” and the second delay signal D2 toggled from a logic “low” level to a logic “high” level at the point of time “T4” to generate the first internal clock signal IRCLK toggled from a logic “low” level to a logic “high” level at a point of time “T3.5”. For example, a toggle point of the first internal clock signal IRCLK may be controlled to have a mean value of a point of time that the first phase signal of the rising clock signal RCLK is toggled and a point of time that the second phase signal of the falling clock signal FCLK is toggled.

Next, the third delay unit 221 of the second synthesizer 22 may retard the falling clock signal FCLK generated at the point of time “T3” by the first delay time to generate the third delay signal D3 toggled from a logic “high” level to a logic “low” level at a point of time “T5”.

The second synthesizer 22 may synthesize the fourth delay signal D4 toggled from a logic “high” level to a logic “low” level at the point of time “T2” and the third delay signal D3 toggled from a logic “high” level to a logic “low” level at the point of time “T5” to generate the second internal clock signal IFCLK toggled from a logic “high” level to a logic “low” level at the point of time “T3.5”. For example, a toggle point of the second internal clock signal IFCLK may be controlled to have a mean value of a point of time that the first phase signal of the falling clock signal FCLK is toggled and a point of time that the second phase signal of the rising clock signal RCLK is toggled.

The phase controller 20 may generate the first internal clock signal IRCLK toggled from a logic “low” level to a logic “high” level at the point of time “T3.5” and the second internal clock signal IFCLK toggled from a logic “high” level to a logic “low” level at the point of time “T3.5”. The first and second internal clock signals IRCLK and IFCLK may be generated to have opposite phases at the same point of time.

Next, the fourth delay unit 222 of the second synthesizer 22 may inversely retard the rising clock signal RCLK generated at a point of time “T6” by the second delay time to generate the fourth delay signal D4 toggled from a logic “low” level to a logic “high” level at a point of time “T7”.

Next, the first delay unit 211 of the first synthesizer 21 may retard the rising clock signal RCLK generated at the point of time “T6” by the first delay time to generate the first delay signal D1 toggled from a logic “high” level to a logic “low” level at a point of time “T8”.

Next, the second delay unit 212 of the first synthesizer 21 may inversely retard the falling clock signal FCLK generated at the point of time “T8” by the second delay time to generate the second delay signal D2 toggled from a logic “high” level to a logic “low” level at a point of time “T9”.

The first synthesizer 21 may synthesize the first delay signal D1 toggled from a logic “high” level to a logic “low” level at the point of time “T8” and the second delay signal D2 toggled from a logic “high” level to a logic “low” level at the point of time “T9” to generate the first internal clock signal IRCLK toggled from a logic “high” level to a logic “low” level at a point of time “T8.5”. For example, a toggle point of the first internal clock signal IRCLK may be controlled to have a mean value of a point of time that the first phase signal of the rising clock signal RCLK is toggled and a point of time that the second phase signal of the falling clock signal FCLK is toggled.

Next, the third delay unit 221 of the second synthesizer 22 may retard the falling clock signal FCLK generated at the point of time “T8” by the first delay time to generate the third delay signal D3 toggled from a logic “low” level to a logic “high” level at a point of time “T10”.

The second synthesizer 22 may synthesize the fourth delay signal D4 toggled from a logic “low” level to a logic “high” level at the point of time “T7” and the third delay signal D3 toggled from a logic “low” level to a logic “high” level at the point of time “T10” to generate the second internal clock signal IFCLK toggled from a logic “low” level to a logic “high” level at the point of time “T8.5”. For example, a toggle point of the second internal clock signal IFCLK may be controlled to have a mean value of a point of time that the first phase signal of the falling clock signal FCLK is toggled and a point of time that the second phase signal of the rising clock signal RCLK is toggled.

The phase controller 20 may generate the first internal clock signal IRCLK toggled from a logic “high” level to a logic “low” level at the point of time “T8.5” and the second internal clock signal IFCLK toggled from a logic “low” level to a logic “high” level at the point of time “T8.5”. The first and second internal clock signals IRCLK and IFCLK may be generated to have opposite phases at the same point of time.

As a result, a data output device including a phase control circuit according to an embodiment may compensate for a phase difference between two differential signals having different phases to generate internal clock signals having the same timing.

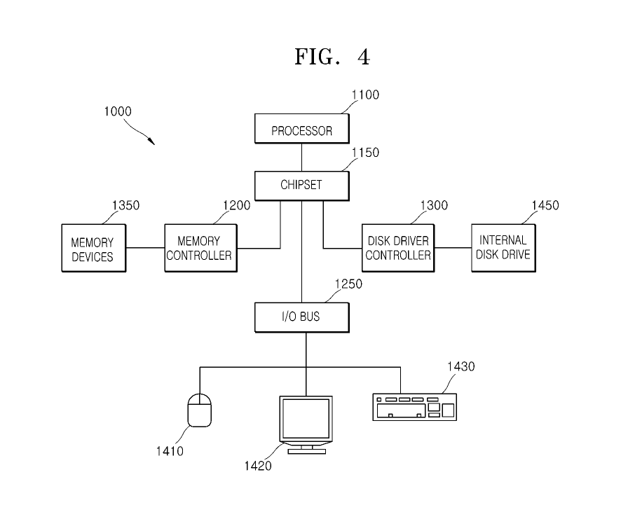

The phase control circuits and/or data output devices discussed above (see FIGS. 1-3) are particular useful in the design of memory devices, processors, and computer systems. For example, referring to FIG. 4, a block diagram of a system employing the phase control circuits and/or data output devices in accordance with the various embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one phase control circuit and/or data output device as discussed above with reference to FIGS. 1-3. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one phase control circuit and/or data output device as discussed above with relation to FIGS. 1-3, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 4 is merely one example of a system employing the phase control circuit and/or data output device as discussed above with relation to FIGS. 1-3. In alternate embodiments, such as cellular phones or digital cameras, the components may differ from the embodiments illustrated in FIG. 4.

What is claimed is:

1. A phase control circuit comprising:
a phase controller suitable for compensating for a phase difference between a first phase signal of a rising clock signal and a second phase signal of a falling clock signal to generate a first internal clock signal and suitable for compensating for a phase difference between a first phase signal of the falling clock signal and a second phase signal of the rising clock signal to generate a second internal clock signal.

2. The phase control circuit of claim 1,
wherein the first phase signal corresponds to a signal that the rising clock signal or the falling clock signal is delayed without phase inversion; and
wherein the second phase signal corresponds to a signal that the rising clock signal or the falling clock signal is delayed with phase inversion.

3. The phase control circuit of claim 1, wherein the rising clock signal and the falling clock signal have different phases opposite to each other.

4. The phase control circuit of claim 1,
wherein a toggle point of the first internal clock signal is controlled to have a mean value of a point of time that the first phase signal of the rising clock signal is toggled and a point of time that the second phase signal of the falling clock signal is toggled; and
wherein a toggle point of the second internal clock signal is controlled to have a mean value of a point of time that the first phase signal of the falling clock signal is toggled and a point of time that the second phase signal of the rising clock signal is toggled.

5. The phase control circuit of claim 1, wherein the phase controller includes:
a first synthesizer suitable for synthesizing the first phase signal of the rising clock signal obtained by retarding the rising clock signal by a first delay time and the second phase signal of the falling clock signal obtained by retarding the falling clock signal by a second delay time to generate the first internal clock signal; and
a second synthesizer suitable for synthesizing the first phase signal of the falling clock signal obtained by retarding the falling clock signal by the first delay time and the second phase signal of the rising clock signal obtained by retarding the rising clock signal by the second delay time to generate the second internal clock signal.

6. The phase control circuit of claim 5,
wherein the first phase signal of the rising clock signal is obtained by retarding the rising clock signal by the first delay time without phase inversion;
wherein the first phase signal of the falling clock signal is obtained by retarding the falling clock signal by the first delay time without phase inversion;
wherein the second phase signal of the rising clock signal is obtained by retarding the rising clock signal by the second delay time with phase inversion; and
wherein the second phase signal of the falling clock signal is obtained by retarding the falling clock signal by the second delay time with phase inversion.

7. The phase control circuit of claim 5, wherein the first synthesizer includes:
a first delay unit coupled between a first node and a second node, the first node configured for receiving the rising clock signal and the second node configured for outputting the first internal clock signal, the first delay unit being suitable for retarding the rising clock signal by the first delay time and outputting the delayed rising clock signal as a first delay signal through the second node; and
a second delay unit coupled between a third node and the second node, the third node configured for receiving the falling clock signal, the second delay unit being suitable for inversely retarding the falling clock signal by the second delay time and outputting the inversely delayed falling clock signal as a second delay signal through the second node.

8. The phase control circuit of claim 7,
wherein the first delay unit includes a plurality of inverters coupled in series between the first node and the second node, and
wherein the first delay time corresponds to a total delay time of the plurality of inverters.

9. The phase control circuit of claim 7,
wherein the second delay unit includes one or more inverters coupled in series between the third node and the second node, and
wherein the number of inverters included in the second delay unit is less or greater than the number of the inverters included in the first delay unit by one inverter.

10. The phase control circuit of claim 7, wherein the first internal clock signal is generated by synthesizing the first and second delay signals.

11. The phase control circuit of claim 5, wherein the second synthesizer includes:
a third delay unit coupled between a third node and a fourth node, the third configured for receiving the falling clock signal and the fourth node configured for outputting the second internal clock signal, the third delay unit being suitable for retarding the falling clock signal by the first delay time and outputting the delayed falling clock signal as a third delay signal through the fourth node; and
a fourth delay unit coupled between a first node and the fourth node, the first node configured for receiving the rising clock signal, the fourth delay unit being suitable for inversely retarding the rising clock signal by the second delay time and outputting the inversely delayed rising clock signal as a fourth delay signal through the fourth node.

12. The phase control circuit of claim 11,
wherein the third delay unit includes a plurality of inverters coupled in series between the third node and the fourth node, and
wherein the first delay time corresponds to a total delay time of the plurality of inverters.

13. The phase control circuit of claim 11,
wherein the fourth delay unit includes one or more inverters coupled in series between the first node and the fourth node, and
wherein the number of inverters included in the second delay unit is less or greater than the number of the inverters included in the first delay unit by one inverter.

14. The phase control circuit of claim 11, wherein the second internal clock signal is generated by synthesizing the third and fourth delay signals.

15. A data output device comprising:
a phase controller suitable for receiving a rising clock signal and a falling clock signal having different phases, suitable for synthesizing a first phase signal of the rising clock signal and a second phase signal of the falling clock signal to generate a first internal clock signal, and suitable for synthesizing a first phase signal of the falling clock signal and a second phase signal of the rising clock signal to generate a second internal clock signal; and
a data input/output (I/O) unit suitable for outputting internal data as output data in synchronization with the first and second internal clock signals.

16. The data output device of claim 15,
wherein the first phase signal corresponds to a signal that the rising clock signal or the falling clock signal is delayed without phase inversion; and
wherein the second phase signal corresponds to a signal that the rising clock signal or the falling clock signal is delayed with phase inversion.

17. The data output device of claim 15,
wherein a toggle point of the first internal clock signal is controlled to have a mean value of a point of time that the first phase signal of the rising clock signal is toggled and a point of time that the second phase signal of the falling clock signal is toggled; and
wherein a toggle point of the second internal clock signal is controlled to have a mean value of a point of time that the first phase signal of the falling clock signal is toggled and a point of time that the second phase signal of the rising clock signal is toggled.

18. The data output device of claim 15, wherein the phase controller includes:
a first synthesizer suitable for synthesizing the first phase signal of the rising clock signal obtained by retarding the rising clock signal by a first delay time and the second phase signal of the falling clock signal obtained by retarding the falling clock signal by a second delay time to generate the first internal clock signal; and
a second synthesizer suitable for synthesizing the first phase signal of the falling clock signal obtained by retarding the falling clock signal by the first delay time and the second phase signal of the rising clock signal obtained by retarding the rising clock signal by the second delay time to generate the second internal clock signal.

19. The data output device of claim 18,
wherein the first phase signal of the rising clock signal is obtained by retarding the rising clock signal by the first delay time without phase inversion;
wherein the first phase signal of the falling clock signal is obtained by retarding the falling clock signal by the first delay time without phase inversion;
wherein the second phase signal of the rising clock signal is obtained by retarding the rising clock signal by the second delay time with phase inversion; and
wherein the second phase signal of the falling clock signal is obtained by retarding the falling clock signal by the second delay time with phase inversion.

20. The data output device of claim 18, wherein the first synthesizer includes:
a first delay unit coupled between a first node and a second node, the first node configured for receiving the rising clock signal and the second node configured for outputting the first internal clock signal, the first delay unit being suitable for retarding the rising clock signal by the first delay time and outputting the delayed rising clock signal as a first delay signal through the second node; and
a second delay unit coupled between a third node and the second node, the third node configured for receiving the falling clock signal, the second delay unit being suitable for inversely retarding the falling clock signal by the second delay time and outputting the inversely delayed falling clock signal as a second delay signal through the second node.

21. The phase control circuit of claim 20,
wherein the first delay unit includes a plurality of inverters coupled in series between the first node and the second node, and
wherein the first delay time corresponds to a total delay time of the plurality of inverters.

22. The phase control circuit of claim 20,
wherein the second delay unit includes one or more inverters coupled in series between the third node and the second node, and
wherein the number of inverters included in the second delay unit is less or greater than the number of the inverters included in the first delay unit by one inverter.

23. The data output device of claim 20, wherein the first internal clock signal is generated by synthesizing the first and second delay signals.

24. The data output device of claim 18, wherein the second synthesizer includes:
a third delay unit coupled between a third node and a fourth node, the third configured for receiving the falling clock signal and the fourth node configured for outputting the second internal clock signal, the third delay unit being suitable for retarding the falling clock signal by the first delay time and outputting the delayed falling clock signal as a third delay signal through the fourth node; and
a fourth delay unit coupled between a first node and the fourth node, the first node configured for receiving the rising clock signal, the fourth delay unit being suitable for inversely retarding the rising clock signal by the second delay time and outputting the inversely delayed rising clock signal as a fourth delay signal through the fourth node.

25. The phase control circuit of claim 24,
wherein the third delay unit includes a plurality of inverters coupled in series between the third node and the fourth node, and
wherein the first delay time corresponds to a total delay time of the plurality of inverters.

26. The phase control circuit of claim 24,
wherein the fourth delay unit includes one or more inverters coupled in series between the first node and the fourth node, and
wherein the number of inverters included in the second delay unit is less or greater than the number of the inverters included in the first delay unit by one inverter.

27. The data output device of claim 24, wherein the second internal clock signal is generated by synthesizing the third and fourth delay signals.
